(19) United States
(12) Patent Application Publication
(10) Pub. No.: US 2007/0248909 A1
(43) Pub. Date: Oct. 25, 2007

(54) Photosensitive Composition for Use in Producing Printing Plate, and Photosensitive Printing Original Plate Laminate and Printing Plate Using the Photosensitive Composition

(76) Inventors: Toshiya Takagi, Kanagawa (JP); Takaaki Hirai, Kanagawa (JP)

Correspondence Address: KNOBBE MARTENS OLSON & BEAR LLP, 2040 MAIN STREET, FOURTEENTH FLOOR, IRVINE, CA, 92614, US

(21) Appl. No.: 11/570,572

(22) PCT Filed: Jun. 14, 2005
(86) PCT No.: PCT/JP05/11213

§ 371 Date: Dec. 13, 2006

(30) Foreign Application Priority Data
Jun. 16, 2004 (JP) 2004-178925

(51) Int. Cl. G03F 7/033

(52) U.S. Cl. 430/270.1

(57) ABSTRACT

The present invention provides a photosensitive composition for use in producing a printing plate, and a photosensitive printing original plate laminate and a printing plate using the photosensitive composition, having durability to various types of printing inks and having excellent printability. The photosensitive composition includes at least a binder resin, a photopolymerizable monomer and a photopolymerization initiator, wherein a combination of an elastomer resin and a terpene resin is used as the binder resin. By using the elastomer resin and the terpene resin in combination, the resultant photosensitive composition has a remarkably improved durability to various types of printing inks, especially to ink components contained in such as UV curing ink or oil-based ink, or to printing inks such as alignment layer solution.

### TECHNICAL FIELD

The present invention relates to a photosensitive composition for use in producing a printing plate, and a photosensitive printing original plate laminate and a printing plate using the photosensitive composition. More particularly, the present invention relates to a photosensitive composition for use in producing a printing plate having durability to various types of printing inks such as ultraviolet (UV) curing ink and oil-based ink and having excellent printability, and a photosensitive printing original plate laminate and a printing plate using the photosensitive composition.

### BACKGROUND ART

As well known, a flexographic printing is a letterpress printing having flexibility, and is excellent in economic properties, versatility and causing no environmental pollution. For this reasons, the flexographic printing is reevaluated, and recently has attracted attention due to an improvement in printing accuracy.

In Japan, as printing methods, offset printing and gravure printing are relatively widely used and silk screen printing is used minor, and the use of letterpress printing as represented by a flexographic printing is relatively a little. However, the flexographic printing has the following advantages over the other printing methods:

(1) The printing plate has a protruding form and flexibility, therefore the printing on a printing object which is not flat or smooth such as a corrugated fiberboard is possible. In addition, the printing can be achieved at relatively high speed and low cost.

(2) Clear printing can be conducted inexpensively on an object having a small area such as a label.

(3) Printing can be made at a high ink density as compared to offset printing, thus enabling clearer printing.

(4) The profile of characters or images is sharp as compared to that obtained by gravure printing.

(5) Aqueous ink can be used and completely solvent-free ink including UV curing ink can be used, causing very little environmental pollution.

(6) The time required for stabilizing the color from the start of the printing is short, and hence the waste of a printing medium such as paper can be reduced, which is advantageous from an economical point of view.

(7) When a part of the printing plate is changed or corrected, it is not necessary to reform the whole printing plate, but only a part of the printing plate can be replaced, so that the cost for maintenance and revision can be lowered.

(8) Printing on various types of objects is possible with a small lot.

In this way, the letterpress printing is a conventional printing technique, and the flexographic printing is also a printing technique conventionally used and has been well known to have the various advantages mentioned above. However, a frequency of the use of the flexographic printing relative to the whole printed matter has not been high.

However, in recent years, as the materials used for printing ink and printing original plate are improved in quality and interests in the environmental issues are increasing, the letterpress printing including flexographic printing is reevaluated, and studies and developments are being vigorously made with a view to positively using the letterpress printing.

Here, a progress in development of the printing original plate itself is as follows.

The flexographic printing plate had been formed from a rubber for a long period, and produced by engraving the rubber layer with a negative image of characters or images to be printed, but a photosensitive resin is begun to use recently. The photosensitive resin generally comprises an elastomeric binder, at least one photopolymerizable monomer, and a photopolymerization initiator. The printing original plate laminate using the photosensitive resin is a plate-form member having at least the photosensitive resin layer formed on a substrate.

In the production of a flexographic printing plate using the printing original plate laminate, first, a film (mask) having a negative pattern of characters or images to be printed is placed on the photosensitive resin layer of the printing original plate laminate, and the photosensitive resin layer is irradiated with actinic rays through the mask. The portion irradiated with actinic radiation undergoes a photopolymerization reaction and then is cured. Subsequently, the uncured portion is washed away with a developing solution, so that a relief pattern corresponding to the image remains, thus forming a flexographic printing plate. In flexographic printing, ink is deposited on the tip portions of the relief pattern and pressed against a printing medium such as paper to apply the ink in a predetermined pattern to the printing medium, thereby obtaining printed matter.

The photosensitive composition used for the letterpress printing technique comprises a binder resin, a photopolymerizable monomer, a photopolymerization initiator and an additional auxiliary agent such as a plasticizer, filler, or a stabilizer. Examples of binder resins include those described in Patent Document 1. As the additional auxiliary agent, a terpene resin is used as a plasticizer or a tackifier for various types of materials. Examples of terpene resins include those described in Patent Document 2 and Patent Document 3.

In Patent Document 2, the terpene resin is used as a plasticizer for facilitating the development of the unexposed portion of the printing original plate and for improving the cured portion in physical properties.

In Patent Document 3, the terpene resin is used for imparting tackiness to the photosensitive composition.

Patent Document 1: Japanese Patent Application Laid-open No. H10-104833 A

Patent Document 2: Japanese Patent Application Laid-open No. H5-134410 A

Patent Document 3: Japanese Patent Application Laid-open No. 2001-281848 A

### DISCLOSURE OF INVENTION

### Problem to be Solved by the Invention

However, with respect to the conventional printing plate, a problem is pointed out such that the printing plate does not have a satisfactory durability to certain ink used, and the patterned, cured resin layer of the printing plate absorbs a component of the printing ink to be swollen during the printing continued. With respect to the ink, the conventional printing plate has an unsatisfactory durability to a monomer component of UV curing ink or a solvent component of oil-based ink, and the printing plate gradually absorbs the component of ink during the printing continued and is lowered in the surface hardness of the printing plate and increased in the thickness of the printing plate. This phenomenon makes the printed design lines or dots thick to cause a marginal zone and the like, leading to a problem in that high-quality printed matter cannot be obtained.

In view of the above, the present invention has been achieved, and an object according to the present invention is to provide a photosensitive composition having excellent durability to an organic solvent component such as isopropyl alcohol, ethyl acetate, propyl acetate, 1-propanol, 1-(1-methylethoxy)-2-propanol, or sec-butyl isopropyl contained in various types of printing ink, particularly ultraviolet (UV) curing ink or oil-based ink, along with a photosensitive printing original plate laminate and a printing plate using the photosensitive composition.

### MEANS FOR SOLVING PROBLEM

The present inventors have conducted extensive studies with a view to solving the above problems. As a result, they have found that, when a terpene resin is added to a conventional photosensitive composition including an elastomer resin, a photopolymerizable monomer and a photopolymerization initiator for use in producing a printing plate, a printing plate having excellent durability to ink can be obtained. The present invention has been completed based on the above finding.

Specifically, the photosensitive composition for use in producing a printing plate according to the present invention comprises an elastomer resin, a terpene resin, a photopolymerizable monomer and a photopolymerization initiator.

In an exemplary embodiment of the photosensitive composition for use in producing a printing plate according to the present invention, it is preferred that a hydrogenated terpene resin is used as the terpene resin. It is preferred that a styrene-isoprene-styrene block copolymer is used as the elastomer resin. It is preferred that the elastomer resin is contained in an amount of 30 to 90 parts by weight and the terpene resin is contained in an amount of 70 to 10 parts by weight, relative to 100 parts by weight of the sum of the elastomer resin and the terpene resin.

The photosensitive printing original plate laminate according to the present invention has on a substrate a photosensitive resin layer formed from at least an elastomer resin, a terpene resin, a photopolymerizable monomer and a photopolymerization initiator. In an exemplary embodiment of the photosensitive printing original plate laminate according to the present invention, it is preferred to form a protective layer covering a surface on the other side of the substrate.

The printing plate according to the present invention is a printing plate having formed on a substrate a cured resin layer having a relief pattern for printing, wherein the patterned, cured resin layer contains at least an elastomer resin and a terpene resin simultaneously as a constituent component.

### EFFECT OF THE INVENTION

The photosensitive resin layer formed using the photosensitive composition for use in producing a printing plate according to the present invention is subjected to exposure and development treatment to form a cured resin layer having a relief pattern for printing. The patterned, cured resin layer has excellent durability to an ink component such as isopropyl alcohol, ethyl acetate, propyl acetate, 1-propanol, 1-(1-methylethoxy)-2-propanol, or sec-butyl isopropyl contained in various types of ink, particularly UV curing ink or an oil-based ink. For this reason, the patterned, cured resin layer is not swollen with the printing ink even during the printing continued for a long time, making it possible to obtain high-quality printed matter. Examples of such UV curing ink include: UV Ace FX Panton Cool Gray, manufactured by Kuboi Ink Co. Ltd.; FD Carton ACE Black, manufactured by Toyo Ink Mfg. Co., Ltd.; UV161, manufactured by T&K TOKA Co. Ltd.; VECTA FLEXO, manufactured by T&K TOKA Co. Ltd.; and UV Gloss OP Varnish, manufactured by T&K TOKA Co. Ltd. Examples of oil-based ink include Flexomax Blue, manufactured by Dainippon Ink & Chemicals Incorporated.

Conventionally, it has not been reported that a terpene resin is used for the photosensitive composition for use in producing a printing plate in order to impart durability to a printing ink. The present invention has been achieved based on the novel finding that a terpene resin is added to improve the durability to a printing ink.

Further, in the photosensitive composition for use in producing a printing plate according to the present invention, the durability to a printing ink can be improved by using a hydrogenated terpene resin as the terpene resin. By using a styrene-isoprene-styrene block copolymer as the elastomer resin, not only can transparency required for forming an exposure pattern be secured, but also more excellent durability to a printing ink can be imparted to the composition. When the elastomer resin is contained in an amount of 30 to 90 parts by weight and the terpene resin is contained in an amount of 70 to 10 parts by weight, relative to 100 parts by weight of the sum of the elastomer resin and the terpene resin, not only can a satisfactory durability to a printing ink be imparted to the composition, but also satisfactory flexibility required for the printing plate can be secured.

The photosensitive printing original plate laminate according to the present invention comprises a substrate and a photosensitive resin layer composed of the photosensitive composition according to the present invention formed on the substrate. By virtue of having such a construction, the photosensitive printing original plate laminate can be preliminarily produced and stored for a predetermined term, although it has an expiration date. Therefore, the photosensitive printing original plate laminate can be immediately used when producing a printing plate, thereby improving the productivity of the printing plate. In addition, in the photosensitive printing original plate laminate according to the present invention, the formation of a protective layer covering a surface on the other side of the substrate facilitates the storage, transport and handling of the laminate.

The printing plate according to the present invention comprises a substrate and a cured resin layer having a relief pattern for printing formed on the substrate, wherein the patterned, cured resin layer contains a combination of an elastomer resin and a terpene resin, and hence the printing plate has excellent durability to various types of a printing ink. Therefore, the patterned, cured resin layer is not swollen with the ink component even during the printing continued for a long time, making it possible to obtain high-quality printed matter. The printing plate according to the present invention can be advantageously used as a printing plate, particularly as a flexographic printing plate for UV curing ink or a flexographic printing plate for oil-based ink.

### BEST MODE(S) FOR CARRYING OUT THE INVENTION

The photosensitive composition for use in producing a printing plate according to the present invention includes at least a binder resin, a photopolymerizable monomer and a photopolymerization initiator, wherein the binder resin includes both an elastomer resin and a terpene resin simultaneously.

By using a combination of an elastomer resin and a terpene resin as binder resin, the resultant printing plate has a remarkably improved durability to printing ink, making it possible to impart excellent printability to the printing plate.

Hereinafter, the photosensitive composition for use in producing a printing plate, and the photosensitive printing original plate laminate and the printing plate using the photosensitive composition according to the present invention will be described in detail in the following order:

[A] Photosensitive composition for use in producing a printing plate

(a) Terpene resin

(b) Elastomer resin

(c) Photopolymerizable monomer

(d) Photopolymerization initiator

[B] Photosensitive printing original plate laminate

[C] Printing plate

[A] Photosensitive Composition for Use in Producing a printing plate

(a) Terpene Resin

In the present invention, the term “terpene resin” means a polymer obtained by homopolymerizing a terpene or copolymerizing a terpene with a monomer copolymerizable with the terpene.

Examples of terpenes used as a raw material for the terpene resin include hydrocarbons having a molecular formula C₁₀H₁₆ and oxygen-containing compounds derived from the hydrocarbons (e.g., alcohol, aldehyde and ketone).

Specific examples of terpenes include hydrocarbons such as α-pinene, β-pinene, myrcene, ocimene, limonene, terpinolene, terpinene, phellandrene, sylvestrene, sabinene, carene, camphene, tricyclene and fenchene; alcohols such as citronellol, geraniol, nerol, linalool, menthol, terpineol, carveol, thujyl alcohol, pinocampheol, fenchyl alcohol and borneol; aldehydes such as citneral, citral, cyclocittal, safranal, phellandral and perillaldehyde; ketones such as tagetone, ionone, menthone, carvomenthone, carvotanacetone, piperitenone, thujone, carone and camphor; oxides such as cineol, pinol and ascaridole; and acids such as citronellic acid. Among these, α-pinene, β-pinene, or limonene is especially preferably used. These terpenes can be used individually or in combination.

Examples of monomers copolymerizable with the terpenes include styrene, α-methylstyrene, o-methylstyrene, m-methylstyrene, p-methylstyrene, chlorostyrene, dichlorostyrene, α-ethylstyrene, methyl-α-methylstyrene, dimethylstyrene, 2,4-diisopropylstyrene, 4-tert-butylstyrene, tert-butoxystyrene, and vinyltoluene.

The polymerization ratio between the terpene and a monomer copolymerizable with the terpene may be 1 to 10 of the terpene to 0 to 5 of the monomer, preferably 1 to 7 of the terpene to 0 to 4 of the monomer, and more preferably 2 to 5 of the terpene to 0 to 3 of the monomer, in terms of the monomer ratio.

The terpene resin obtained by homopolymerizing a terpene or copolymerizing a terpene with a monomer copolymerizable with the terpene may have in its molecular structure a carbon-carbon unsaturated bond or an oxygen-carbon unsaturated bond. In the present invention, a hydrogenated terpene resin obtained by partially or completely hydrogenating the unsaturated bond is preferably used, and a completely hydrogenated terpene resin is especially preferably used. By using the hydrogenated terpene resin, the durability to the printing ink can be further improved.

Examples of commercially available hydrogenated terpene resins include Clearon P series, Clearon M series and Clearon K series (each manufactured by Yasuhara Chemical Co., Ltd.).

The terpene resin may have an average molecular weight of 300 to 1,500, preferably 400 to 1,000, more preferably 500 to 800. When the average molecular weight of the terpene resin is less than 300, it is difficult to synthesize such a resin. On the other hand, when the average molecular weight of the terpene resin is larger than 1,500, the flexibility disadvantageously tends to be unsatisfactory, thereby causing the printing original plate laminate to suffer a damage.

It is preferred that the terpene resin is incorporated in an amount of 1 to 90 parts by weight, relative to 100 parts by weight of the sum of the elastomer resin mentioned below and the terpene resin. When the amount of the terpene resin is less than 1 part by weight, the durability to printing ink is unsatisfactory. On the other hand, when the amount of the terpene resin is more than 90 parts by weight, the flexibility disadvantageously tends to be unsatisfactory, thereby causing the printing original plate laminate to suffer damage. For imparting satisfactory durability to the printing ink to the printing plate while securing satisfactory flexibility required for the printing plate, it is preferred that the terpene resin is incorporated in an amount of 10 to 70 parts by weight, relative to 100 parts by weight of the sum of the elastomer resin and the terpene resin.

(b) Elastomer Resin

In the present invention, as examples of the elastomer resins, there can be mentioned resins other than the terpene resins, which are homopolymers, copolymers or mixtures thereof, and which are polymers having elastomeric properties and being soluble, swellable or dispersible in and removable by an aqueous or organic solvent developing solution. Examples of binders include polybutadiene, polyisoprene, polydiolefin, vinyl aromatic compound/diolefin copolymers and block copolymers, styrene/butadiene copolymers, styrene/isoprene copolymers, diolefin/acrylonitrile copolymers, ethylene/propylene copolymers, ethylene/propylene/diolefin copolymers, ethylene/acrylic acid copolymers, diolefin/acrylic acid copolymers, diolefin/acrylate/acrylic acid copolymers, ethylene/(meth)acrylic acid/(meth)acrylate copolymers, polyamide, polyvinyl alcohol, polyvinyl alcohol/polyethylene glycol graft copolymers, amphoteric interpolymers, cellulose such as alkyl cellulose, hydroxyalkyl cellulose and nitrocellulose, ethylene/vinyl acetate copolymers, cellulose acetatebutyrate, polybutylal, cyclic rubbers, styrene/acrylic acid copolymers, polyvinyl pyrrolidone, copolymers of polyvinyl pyrrolidone and vinyl acetate, chloroprene polymers, styrene-chloroprene copolymers, acrylonitrile-butadiene copolymers, acrylonitrile-isoprene copolymers, acrylonitrile-chloroprene copolymers, methyl methacrylate-butadiene copolymers, methyl methacrylate-isoprene copolymers, methyl methacrylate-chloroprene copolymers, methyl acrylate-butadiene copolymers, methyl acrylate-isoprene copolymers, methyl acrylate-chloroprene copolymers, acrylonitrile-butadiene-styrene copolymers, acrylonitrile-isoprene-styrene copolymers, acrylonitrile-chloroprene-styrene copolymers, epichlorohydrin polymers, epichlorohydrin-ethylene oxide copolymers, epichlorohydrin-propylene oxide copolymers, epichlorohydrin rubbers, chlorinated polyethylene, vinyl chloride copolymers, vinylidene chloride copolymers, chlorinated polypropylene, chlorinated ethylene-propylene rubbers, ethyl acrylate-acrylonitrile copolymers, butyl acrylate-acrylonitrile copolymers, methyl methacrylate-acrylonitrile copolymers, and butyl acrylate-styrene-acrylonitrile copolymers. The polymers may be used individually or in combination. Other examples include resins disclosed in the specifications of U.S. Pat. Nos. 3,458,311, 4,442,302, 4,361,640, 3,794,494, 4,177,074, 4,431,723 and 4,517,279, which are binders soluble or dispersible in an aqueous developing solution, and resins disclosed in the specifications of U.S. Pat. Nos. 4,323,636, 4,430,417 and 4,045,231, which are soluble, swellable, or dispersible in an organic solvent developing solution.

In the present invention, a styrene/isoprene copolymer or a styrene/butadiene copolymer is preferably used, and a styrene-isoprene-styrene block copolymer is especially preferably used. By using a styrene-isoprene-styrene block copolymer, not only can transparency required for forming an exposure pattern be secured, but also the durability to a printing ink can be further improved.

The elastomer resin may be incorporated in an amount of 10 to 99 parts by weight, preferably 30 to 90 parts by weight, relative to 100 parts by weight of the sum of the elastomer resin and the terpene resin.

(c) Photopolymerizable Monomer

As one type of monomer or more contained in the photosensitive resin layer used in the present invention, it is necessary to use a monomer compatible with the binder in order to form a transparent photosensitive resin layer. Examples of the monomers include monomers constituting the binder; polybutadiene diacrylate, polybutadiene dimethacrylate, polyisoprene diacrylate and polyisoprene dimethacrylate; aromatic vinyl monomers such as α-methylstyrene, m-methylstyrene, and p-methoxystyrene; α,β-ethylenically unsaturated nitrile compounds such as acrylonitrile and methacrylonitrile; acrylates of alkyl alcohol having 1 to 23 carbon atoms such as methyl acrylate, ethyl acrylate, propyl acrylate, n-butyl acrylate, isobutyl acrylate and t-butyl acrylate, and corresponding methacrylates; acrylates of hydroxyalkyl alcohol such as 2-hydroxyethyl acrylate and 2-hydroxypropyl acrylate, and corresponding methacrylates; acrylates of alkoxy alkyleneglycol such as methoxy ethyleneglycol and methoxy propyleneglycol, and corresponding methacrylates; unsaturated polycarboxylic acid monoesters such as monoethyl maleate, monomethyl fumarate and monoethyl itaconate; diesters such as dimethyl maleate, diethyl maleate, dibutyl maleate, dioctyl maleate, diethyl fumarate, dibutyl fumarate, dioctyl fumarate, dimethyl itaconate, diethyl itaconate, dibutyl itaconate and dioctyl itaconate; acrylamides such as acrylamide, methacrylamide, N,N′-methylenebisacrylamide and N,N′-hexamethylenebisacrylamide, and corresponding methacrylamides; diacrylates of glycol such as ethylene glycol diacrylate and polyalkylene glycol (having 2 to 23 alkylene glycol units), and corresponding methacrylates; diacrylates, triacrylates, tetraacrylates and oligo acrylates of a trihydric or more alcohol, i.e., polyhydric alcohol such as glycerol, pentaerythritol, trimethylolalkane or tetramethylolalkane (examples of alkanes include methane, ethane and propane), and corresponding methacrylates; and acrylates having an acid functional group such as 2-(acryloyloxy)ethyl succinate, 2-(acryloyloxy)ethyl hexahydrophthalate and 2-(acryloyloxy)ethyl phosphate, and corresponding methacrylates. These photopolymerizable ethylenically unsaturated monomers may be used individually or in combination. In addition, other examples include monomers described in the specifications of U.S. Pat. Nos. 4,323,636, 4,753,865, 4,726,877 and 4,894,315. The photopolymerizable monomers may be used individually or in combination. Especially preferred monomers are polybutadiene diacrylate and 1,6-hexanediol diacrylate.

The monomer may be contained in an amount of 5 to 30 parts by weight, preferably 10 to 20 parts by weight, relative to 100 parts by weight of the sum of the elastomer resin and the terpene resin. When the amount of the monomer contained is smaller than the lower limit of the range, the film cured after the exposure is lowered in wear resistance and chemical resistance. When the amount of the monomer is larger than the upper limit of the range, the elastomeric properties of the photosensitive resin layer become poor, so that the resultant printing plate is not preferred as a flexographic printing plate.

(d) Photopolymerization Initiator

As the photopolymerization initiator, one generally known can be used. Examples of such initiators include aromatic ketones such as benzophenone; benzoin ethers such as benzoin methyl ether, benzoin ethyl ether, benzoin isopropyl ether, α-methylolbenzoin methyl ether, α-methoxybenzoin methyl ether and 2,2-diethoxyphenylacetophenone; substituted or unsubstituted polynuclear quinones; 1-hydroxycyclohexyl phenyl ketone, 2,2-dimethoxy-1,2-diphenylethan-1-one, 2-methyl-1-[4-(methylthio)phenyl]-2-morpholinopropan-1-one, 2-benzyl-2-dimethylamino-1-(4-morpholinophenyl)-butan-1-one, 2-hydroxy-2-methyl-1-phenylpropan-1-one, 2,4,6-trimethylbenzoyldiphenylphosphine oxide, 1-[4-(2-hydroxyethoxy)phenyl]-2-hydroxy-2-methyl-1-propan-1-one, 2,4-diethylthioxanthone, 2-chlorothioxanthone, 2,4-dimethylthioxanthone, 3,3-dimethyl-4-methoxybenzophenone, benzophenone, 1-chloro-4-propoxythioxanthone, 1-(4-isopropylphenyl)-2-hydroxy-2-methylpropan-1-one, 1-(4-dodecylphenyl)-2-hydroxy-2-methylpropan-1-one, 4-benzoyl-4′-methyldimethyl sulfide, 4-dimethylaminobenzoic acid, methyl 4-dimethylaminobenzoate, ethyl 4-dimethylaminobenzoate, butyl 4-dimethylaminobenzoate, 2-ethylhexyl 4-dimethylaminobenzoate, 2-isoamyl 4-dimethylaminobenzoate, 2,2-diethoxyacetophenone, benzyl dimethyl ketal, benzyl-p-methoxy ethyl acetal, methyl o-benzoylbenzoate, bis(4-dimethylaminophenyl) ketone, 4,4′-bisdiethylaminobenzophenone, 4,4′-dichlorobenzophenone, benzyl, benzoin, benzoin methyl ether, benzoin ethyl ether, benzoin isopropyl ether, benzoin n-butyl ether, benzoin isobutyl ether, p-dimethylaminoacetophenone, p-tert-butyltrichloroacetophenone, p-tert-butyldichloroacetophenone, 2-(o-chlorophenyl)-4,5-diphenylimidazolyl dimer, thioxanthone, 2-methylthioxanthone, 2-isopropylthioxanthone, dibenzosuberone, α,α-dichloro-4-phenoxyacetophenone, pentyl 4-dimethylaminobenzoate, 9-phenylacridine, 1,7-bis-(9-acridinyl)heptane, 1,5-bis-(9-acridinyl)pentane, and 1,3-bis-(9-acridinyl)propane. In addition, other examples include initiators disclosed in the specifications of U.S. Pat. Nos. 4,460,675 and 4,894,315. The initiators may be used individually or in combination.

The initiator may be contained in an amount of 0.001 to 10% by weight, based on the total weight of the photosensitive composition for use in producing a printing plate according to the present invention.

Further, in the photosensitive resin composition according to the present invention, if necessary, a dye, a pigment, a polymerization inhibitor, an antioxidant, or a photo-degradation inhibitor can be added to improve the performance thereof.

[B] Photosensitive Printing Original Plate Laminate

The photosensitive printing original plate laminate according to the present invention is a laminate having a substrate, and a photosensitive resin layer which is formed on the substrate and comprised of the photosensitive composition for use in producing a printing plate according to the present invention.

With respect to the method for forming the photosensitive resin layer, there is no particular limitation, and the method can be arbitrarily selected from methods generally used for stacking a photosensitive layer on a substrate in the production of a photosensitive printing original plate laminate. For example, a terpene resin, an elastomer resin, a photopolymerizable monomer, a photopolymerization initiator and other components are mixed together to prepare a photosensitive resin composition, and the composition is hot-melt shaped and calendered so as to have a desired thickness. In another method, the photosensitive resin composition is melted, mixed, deaerated, filtered and then extruded into between a substrate and a temporary cover sheet using an extruder, and calendered so as to have a desired thickness. In still another method, a substrate and a cover sheet are placed in a mold and the photosensitive resin composition is injected to between them.

By using these methods, a coating layer of the photosensitive resin composition is formed on a substrate, and then the coating layer is cured to form a photosensitive resin layer.

The photosensitive resin layer generally has a thickness in the range of from 0.1 to 10.0 mm, preferably 0.5 to 7.0 mm.

With respect to the substrate layer constituting the photosensitive printing original plate laminate according to the present invention, there is no particular limitation as long as it satisfies physical properties such as mechanical strength required in the printing conditions employed, and any substrate comprised of, for example, a known metal, plastic film, paper, or a composite thereof used in a general flexographic printing plate can be used. These include polymer films comprised of an addition polymerization polymer or a linear condensed polymer, transparent foams, woven fabric, nonwoven fabric, such as glass fiber fabric, and metals such as steel and aluminum. For easily conducting the back exposure, it is preferred that the substrate is transparent to exposure light. More preferred examples of substrates include polyethylene, polypropylene and polyester films, and especially preferred is a polyethylene terephthalate film. As the film, a film having a thickness of 50 to 400 μm, preferably a film having a thickness of 75 to 300 μm is used. The substrate layer may be, if necessary, covered with a thin adhesive layer between the photosensitive resin layer and the substrate layer. Examples of adhesive layers include polyester resins, urethane resins and ethyl cellulose, and an adhesive layer comprised of a mixture of polycarbonate, a phenoxy resin and polyfunctional isocyanate is preferably used.

In the present invention, if necessary, it is preferred to form a protective layer on a surface on the other side of the substrate layer. As the protective layer, preferred is a polyethylene terephthalate film, polypropylene film or polyethylene film having silicone coated or baked and having a thickness of about 15 to 125 μm. The protective layer is temporarily stacked for facilitating the storage, transport and handling of the laminate, and the protective layer is removed when producing a printing plate to expose the photosensitive resin layer, so that the photosensitive resin layer is irradiated with pattern light. The protective layer may be, if necessary, covered with a thin anti-block layer between the photosensitive resin layer and the protective layer. Examples of the anti-block layers include polypropylene, polyester, polystyrene, cellulose derivatives and polyamide resins.

In the present invention, it is preferred that, if necessary, a mask material layer is formed on the photosensitive resin layer. A mask material layer opaque to exposure light is formed on the photosensitive resin layer, and patterned so that exposure light passes through part of the mask material layer to form a mask image layer. Thereafter, by an irradiation with exposure light through the mask image layer, a pattern for printing can be formed on the photosensitive resin layer. Therefore, the productivity of a letterpress printing plate can be further improved.

As the method for patterning so that exposure light passes through a part of the mask material layer to form a mask image layer, a method is mainly used in which an infrared abrasion layer comprised of an infrared sensitive material is formed as a mask material layer, and the infrared abrasion layer is subjected to selective abrasion (burning off) using an infrared laser to form a negative pattern. The infrared abrasion layer can be referred in, for example, Japanese, Patent Publication No. 2916408, Japanese Patent Application Laid-open Nos. 2003-35954, 2003-35955, H11-153865, H9-166875 and 2001-324815, and Japanese Patent Publication No. 2773981.

[C] Printing Plate

The printing plate according to the present invention is a letterpress printing plate having on a substrate a cured resin layer having a relief pattern for printing,

wherein the patterned, cured resin layer contains at least a, combination of an elastomer resin component and a terpene resin component. It is preferred that the patterned, cured resin layer is formed by subjecting the photosensitive composition for use in producing a printing plate according to the present invention to photocuring reaction. The form of the elastomer resin component and terpene resin component in the patterned, cured resin layer varies depending on the conditions for photocuring reaction, and is presumed to be in a crosslinked form due to the photocuring reaction of the photopolymerizable monomer, or in an uncrosslinked or unreacted form. In the present invention, the elastomer resin component and terpene resin component may be contained in any form in the patterned, cured resin layer.

The printing plate according to the present invention using the photosensitive printing original plate laminate is produced by subjecting the photosensitive resin layer to exposure through a mask to cure the photosensitive resin layer of the pattern portion, and removing by a developing solution the exposure light unirradiated region of the photosensitive resin layer, which is not irradiated with the exposure light and hence is in an uncured state, to change the photosensitive resin layer to a patterned, cured resin layer.

In an exemplary embodiment, the photosensitive printing original plate laminate is, if necessary, subjected to back exposure from the side of the substrate layer, and then the protective layer (slip sheet) of the photosensitive printing original plate laminate is removed to expose the photosensitive resin layer. Then, the laminate is subjected to main exposure through a mask to cure the photosensitive resin layer of the pattern portion. In the main exposure, the photosensitive resin layer is irradiated with pattern light according to the mask pattern, and the region irradiated with the exposure light undergoes a crosslinking reaction and is then cured.

When a mask material layer, such as an infrared abrasion layer, is formed on the photosensitive resin layer, the infrared abrasion layer is removed using an infrared laser to form a mask image, followed by main exposure using the mask image layer as a mask.

The uncured portion, which is not irradiated with exposure light, is then removed by a developing solution so that a pattern for printing appears, followed by drying. After the drying, if necessary, post exposure may be carried out.

As an exposure apparatus used in the exposure, for example, an actinic radiation apparatus generally used in the production of a flexographic plate can be used. As radiation ray, ultraviolet light or visible light having a wavelength of 150 to 800 nm can be used, and preferred is ultraviolet light having a wavelength of 320 to 450 nm. As the light source, for example, a low-pressure mercury lamp, a high-pressure mercury lamp, a deuterium lamp, a metal halide lamp, an argon resonance lamp, a xenon lamp or excimer laser can be used.

The developing solution used in the development treatment may be any of an organic solution, water, and an aqueous or semi-aqueous solution as long as it has a property of dissolving the photosensitive resin layer, and the developing solution is selected depending on the chemical properties of the resin to be removed. Examples of appropriate organic solvent developing solutions include aromatic or aliphatic hydrocarbon solvents, aliphatic or aromatic halohydrocarbon solvents, and mixtures of the above solvent and an appropriate alcohol. The semi-aqueous developing solution contains water or an organic solvent miscible with water, and an alkaline material. Examples of the aqueous developing solutions include aqueous solutions obtained by dissolving in water, e.g., an ester such as heptyl acetate or 3-methoxybutyl acetate; a hydrocarbon such as petroleum fraction, toluene or decalin; a chlorine solvent such as tetrachloroethylene; an amine such as monoethanolamine, diethanolamine or triethanolamine; sodium hydroxide, potassium hydroxide, sodium carbonate, or ammonia. Alternatively, a mixture of the above solvent and an alcohol such as propanol, butanol or pentanol can be used. In washing solvent, an arbitrary method such as dipping, spraying from a nozzle or brushing using a brush can be employed.

In the production of the printing plate according to the present invention, the printing original plate laminate is set on a drum in a cylindrical form, and subjected to exposure and development treatment, thereby further improving the productivity of the plate for printing.

### EXAMPLES

The present invention will be explained more specifically based on Examples below. Note that the present invention is not limited by the Examples.

### Examples 1 to 3 and Comparative Examples 1 and 2

(Preparation of Flexographic Printing Plate)

A styrene-isoprene-styrene block copolymer (trade name: D-1107; manufactured by KRATON Co., Ltd.) as a thermoplastic elastomer, and a hydrogenated terpene resin (trade name: Clearon p-125; manufactured by YASUHARA CHEMICAL Co., Ltd.) were mixed together in the formulation ratio shown in Table 1 below. 75% by weight of the resultant mixture, 8.7% by weight of 1,6-hexanediol diacrylate, 15% by weight of polybutadiene-terminated acrylate (trade name: BAC-45; manufactured by OSAKA ORGANIC CHEMICAL INDUSTRY LTD.), and 1.3% by weight of benzyl dimethyl ketal (trade name: Irgacure 651; manufactured by Ciba Specialty Chemicals K.K.) were charged into a twin-screw kneader, and shaped using a T-die into a sheet having a thickness of 2 mm. The obtained sheet was laminated to a polyester sheet (substrate layer) having a thickness of 125 μm, and the other surface of the sheet was laminated to a polyester sheet (protective layer) having formed thereon an anti-block layer comprised of a polyamide resin layer, thus preparing a printing original plate laminate comprising four layers, i.e., substrate layer-photosensitive resin layer-anti-block layer-protective layer, which were stacked on one another and integrated.

TABLE 1

Formulation
(% by weight)

| | D-1107 | Clearon P-125 |
|---|---|---|
| Example 1 | 90 | 10 |
| Example 2 | 50 | 50 |
| Example 3 | 30 | 70 |
| Comparative | 100 | 0 |
| Example 1 | | |
| Comparative | 0 | 100 |
| Example 2 | | |

Each printing original plate laminate was then set on a drum in a cylindrical form, and successively subjected to back exposure, main exposure, development, drying and post exposure to form a flexographic printing plate. The printing original plate laminate in Comparative Example 2 was unsatisfactory in flexibility, and hence the printing original plate laminate was damaged when set on the drum. Therefore, the following evaluation of the performance of the flexographic printing plate was conducted with respect to Examples 1 to 3 and Comparative Example 1.

(Evaluation of Flexographic Printing Plate)

A plate having a size of 3 cm×3 cm was cut out from each of the printing plates in Examples 1 to 3 and Comparative Example 1, and immersed in the UV curing ink or oil-based ink shown below for 48 hours. A reduction of the plate surface hardness (difference in the hardness, as measured by a hardness tester in accordance with JIS K 6301A, between before and after the immersion of the plate in ink) and an increase of the photosensitive layer thickness are respectively shown in Tables 2 and 3.

Ink 1: UV Curing Ink

(UV Ace FX Panton Cool Gray, Manufactured by Kuboi Ink Co. Ltd.)

Ink 2: UV Curing Ink

(FD Carton ACE Black, manufactured by Toyo Ink Mfg. Co., Ltd.)

Ink 3: UV Curing Ink

(UV161, manufactured by T&K Toka Co. Ltd.)

Ink 4: UV Curing Ink

(Vecta Flexo, Manufactured by T&K Toka Co. Ltd.)

Ink 5: UV Curing Ink

(UV Gloss OP Varnish, manufactured by T&K TOKA Co. Ltd.)

Ink 6: Oil-Based Ink

(flexomax blue: containing isopropyl alcohol, ethyl acetate, propyl acetate, 1-propanol, 1-(1-methylethoxy)-2-propanol, sec-butyl isopropyl, manufactured by Dainippon Ink & Chemicals Incorporated)

TABLE 2
Reduction of plate surface hardness (°)

| | Ink 1 | Ink 2 | Ink 3 | Ink 4 | Ink 5 | Ink 6 |
|---|---|---|---|---|---|---|
| Example 1 | 2 | 2 | 2 | 2 | 2 | 2 |
| Example 2 | 1 | 1 | 1 | 1 | 1 | 1 |
| Example 3 | 0.5 | 0.5 | 0.5 | 0.5 | 0.5 | 0.5 |
| Comparative | 4 | 4 | 4 | 4 | 4 | 6 |
| Example 1 | | | | | | |
| Comparative | — | — | — | — | — | — |
| Example 2 | | | | | | |

TABLE 3
Increase of photosensitive layer thickness (μm)

| | Ink 1 | Ink 2 | Ink 3 | Ink 4 | Ink 5 | Ink 6 |
|---|---|---|---|---|---|---|
| Example 1 | 10 | 10 | 10 | 10 | 10 | 20 |
| Example 2 | 5 | 5 | 5 | 5 | 5 | 10 |
| Example 3 | 3 | 3 | 3 | 3 | 3 | 5 |
| Comparative | 30 | 30 | 30 | 30 | 30 | 60 |
| Example 1 | | | | | | |
| Comparative | — | — | — | — | — | — |
| Example 2 | | | | | | |

From the above results, it is found that, in Examples 1 to 3 in which an elastomer resin and a terpene resin were used in combination, the reduction of the plate surface hardness and the increase of the photosensitive layer thickness are substantially zero or very slight, which indicates that each plate has excellent durability to UV curing ink or oil-based ink.

On the other hand, in Comparative Example 1 in which no terpene resin was used, the durability to UV curing ink or oil-based ink was unsatisfactory, and both the reduction of the plate surface hardness and the increase of the photosensitive layer thickness were noticeable.

### INDUSTRIAL APPLICABILITY

As mentioned above, the photosensitive composition for use in producing a printing plate according to the present invention includes at least a binder resin, a photopolymerizable monomer and a photopolymerization initiator, wherein a combination of an elastomer resin and a terpene resin is used as the binder resin. By using the elastomer resin and the terpene resin in combination, the resultant printing plate has a remarkably improved durability to printing ink.

By using the photosensitive composition for use in producing a printing plate according to the present invention having the above characteristic feature, a photosensitive printing original plate laminate and a printing plate having excellent printability can be produced, and advantageously used as a letterpress printing plate particularly for UV curing ink or oil-based ink.

1. A photosensitive composition for use in producing a printing plate comprising:
a binder resin;
a photopolymerizable monomer; and
a photopolymerization initiator,
wherein the binder resin comprises a combination of an elastomer resin and a terpene resin.

2. The photosensitive composition according to claim 1, wherein the terpene resin is a hydrogenated terpene resin.

3. The photosensitive composition according to claim 1, wherein the elastomer resin is a styrene-isoprene-styrene block copolymer.

4. The photosensitive composition according to claim 1, wherein the elastomer resin is contained in an amount of 30 to 90 parts by weight and the terpene resin is contained in an amount of 70 to 10 parts by weight, relative to 100 parts by weight of the sum of the elastomer resin and the terpene resin.

5. A photosensitive printing original plate laminate comprising:
a substrate; and
a photosensitive resin layer provided on the substrate,
wherein the photosensitive resin layer is comprised of a photosensitive composition for use in producing a printing plate, the photosensitive composition comprises:
a binder resin;
a photopolymerizable monomer; and
a photopolymerization initiator,
wherein the binder resin comprises a combination of an elastomer resin and a terpene resin.

6. The photosensitive printing original plate laminate according to claim 5, further comprising a protective layer provided on a surface on the other side of the substrate.

7. A printing plate comprising:
a substrate; and
a cured resin layer having a relief pattern for printing provided on the substrate,
wherein the patterned, cured resin layer comprises an elastomer resin component and a terpene resin component as a constituent component.

8. The printing plate according to claim 7, wherein the printing plate is a flexographic printing plate for ultraviolet curing ink.

9. The printing plate according to claim 7, wherein the printing plate is a flexographic printing plate for oil-based ink.
